(19) United States
(12) Patent Application Publication
(10) Pub. No.: US 2021/0329790 A1
(43) Pub. Date: Oct. 21, 2021

(54) METHOD OF MANUFACTURING A STRUCTURE HAVING CONDUCTIVE LINES

(71) Applicant: INDUSTRIAL TECHNOLOGY RESEARCH INSTITUTE, Hsinchu (TW)

(72) Inventors: Yu-Ming WANG, Hsinchu City (TW); Sheng-Yu LIN, Zhunan Township (TW); Wei-Yuan CHEN, Taichung City (TW); Kai-Jiun WANG, Tianwei Township (TW)

(21) Appl. No.: 17/361,902

(22) Filed: Jun. 29, 2021

Related U.S. Application Data
(62) Division of application No. 16/158,887, filed on Oct. 12, 2018.
Application No. 16/158,887 is a continuation-in-part of application No. 14/583,467, filed on Dec. 26, 2014, now abandoned.

(30) Foreign Application Priority Data
Nov. 28, 2014 (TW) 103141353

(51) Int. Cl. H05K 3/18; H05K 1/09

(52) U.S. Cl. CPC H05K 3/182; H05K 3/387; H05K 2203/0709; H05K 1/09

(57) ABSTRACT

A method of manufacturing a structure having conductive lines is disclosed by forming a patterned catalyst material layer on a substrate; activating the patterned catalyst material layer to form an activated patterned catalyst material layer including activated catalysts; and growing a conductive layer on the activated catalysts of the activated patterned catalyst material layer. The patterned catalyst material layer is formed from a catalyst material including 40 wt % to 90 wt % of polymer and 10 wt % to 60 wt % of catalyzer. An uppermost portion of the activated patterned catalyst material layer includes the activated catalysts, and the activated catalysts include metal reduced from the catalyzer. The pattern of the conductive layer corresponds to that of the patterned catalyst material layer. The structure of the conductive line of the disclosure has the characteristics of high conductivity.

### CROSS-REFERENCE TO RELATED APPLICATION

This is a divisional application of U.S. application Ser. No. 16/158,887, filed Oct. 12, 2018, which is a continuation-in-part application of U.S. application Ser. No. 14/583,467, filed Dec. 26, 2014, which claims the benefit of Taiwan Application No. 103141353, filed Nov. 28, 2014, the contents of which are incorporated herein by reference.

### TECHNICAL FIELD

The disclosure relates to a method of manufacturing a structure having conductive lines.

### BACKGROUND

Printed electronic products have great potential of development in the future market, and the feature of those printed electronic products in common is the continual decrease in the overall sizes. Size of each component equipped in the printed electronic product has to be restrictedly limited in order to satisfy the product requirements of being compact in size and lighter in weight in the market. Take the conductive lines for example, which are the most commonly used component in the printed electronic product. The line widths of the conductive lines have been reduced from couple hundreds micrometers to several micrometers. The derived theme is the perennial issue of process ability and production cost. The printing technology can be rapid and continuous processing, low power consumption and low pollution, which is regarded as the advanced technology for manufacturing the electronic product of the next generation. To deal with the trend of the size reduction of the printed electronic product, it would be very important that consideration is given to both the decrease of line width and the improvement of the electrical characteristics of the printed conductive lines.

### SUMMARY

The disclosure relates to a structure of conductive lines and method of manufacturing the same. According to one embodiment, a structure having conductive lines on a substrate can be obtained by forming a patterned catalyst material layer as the trace pattern by printing process, activating the patterned catalyst material layer, followed by growing a conductive layer on the activated patterned catalyst material layer. The structure of conductive lines of the embodiment possesses high conductivity. Accordingly, the electronic products applied with the structure of conductive lines of the embodiment possess several advantages, such as good and stable conductivity of conductive lines, high yield of production and low-production cost. Also, the manufacturing method adopts rapid and low-pollution procedures.

According to one embodiment, a structure having conductive lines on a substrate is provided, and the conductive lines comprise an activated patterned catalyst material layer on a substrate, and the activated patterned catalyst material layer formed from a catalyst material comprising 40 wt % to 90 wt % of polymer and 10 wt % to 60 wt % of catalyzer, wherein an uppermost portion of the activated patterned catalyst material layer comprises activated catalysts; and a conductive layer formed on the activated catalysts of the activated patterned catalyst material layer, and a pattern of the conductive layer corresponding to the activated patterned catalyst material layer, wherein the catalyzer comprises one or more materials selected from organic-metallic compounds, metal particles, or a combination thereof, and the activated catalysts of the activated patterned catalyst material layer comprises metal reduced from the catalyzer.

According to one embodiment, a method of manufacturing a structure having conductive lines is provided, comprising providing a substrate; forming a patterned catalyst material layer on the substrate, and the patterned catalyst material layer formed from a catalyst material at least comprising 40 wt % to 90 wt % of polymer and 10 wt % to 60 wt % of catalyzer, wherein the catalyzer comprises one or more materials selected from organic-metallic compounds, metal particles, or a combination thereof; activating the patterned catalyst material layer to form an activated patterned catalyst material layer on the substrate, wherein an uppermost portion of the activated patterned catalyst material layer comprises activated catalysts after activating, and the activated catalysts comprises metal reduced from the catalyzer; and contacting metal ions as provided to the activated patterned catalyst material layer, so as to form a conductive layer on the activated catalysts of the activated patterned catalyst material layer.

The disclosure will become apparent from the following detailed description of the preferred but non-limiting embodiments. The following description is made with reference to the accompanying drawings.

### BRIEF DESCRIPTION OF THE DRAWINGS

FIG. 1 is a method of manufacturing of a structure of conductive lines according to the embodiment of the disclosure.

FIG. 2 illustrates a method of manufacturing of a structure of conductive lines by a gravure offset printing process according to an embodiment of the disclosure.

FIG. 3 is a method of manufacturing of a structure of conductive lines on a substrate according to one of the embodiments.

FIG. 4 illustrates a structure of conductive lines manufactured according to a method of one embodiment of the disclosure.

FIG. 5 shows the relationship of conductivity versus cross-sectional area of the conductive lines manufactured by the photolithography process, the printing process and the embodied manufacturing method.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Below, exemplary embodiments of organic light emitting devices will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

The exemplary embodiments of the disclosure are directed to a structure of conductive lines and method of manufacturing the same. The conductive lines of the embodiment can be obtained by forming a patterned catalyst material layer having a trace pattern using a printing process (such as a gravure offset printing process), and then growing a dense conductive layer at the patterned catalyst material layer directly. Therefore, the conductive lines of the embodiment possesses high conductivity and high yield of production (i.e. since the notch defect typically occured in the photolithography process would not be shown in the structure of the embodiment, the problem of disconnection lines can be successfully solved), so that the electronic product applied with the structure of conductive lines of the embodiment possesses good and stable conductivity. Also, a method of manufacturing the structure of conductive lines of the embodiment is simple, and adopts low-pollution and low-production cost procedures, which is suitable for mass production.

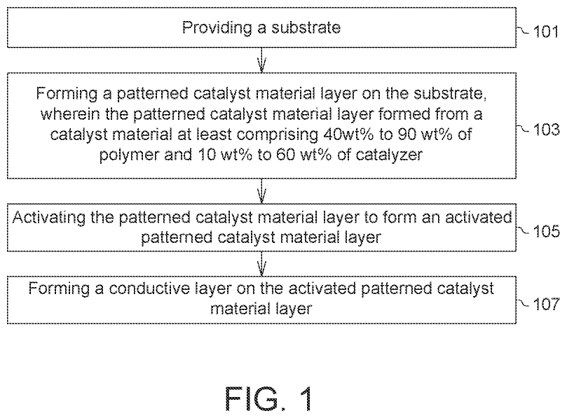

FIG. 1 is a method of manufacturing of a structure of conductive lines according to the embodiment of the disclosure. In step 101, a substrate is provided. A patterned catalyst material layer is formed on the substrate, such as printing related catalyst material by a gravure offset printing process, and the patterned catalyst material layer formed from a catalyst material at least comprising 40 wt % to 90 wt % of polymer and 10 wt % to 60 wt % of catalyzer, as shown in step 103. In one embodiment, the catalyzer may include one or more materials selected from organic-metallic compounds, metal particles, or a combination thereof. Then, the patterned catalyst material layer is activated to form an activated patterned catalyst material layer, as shown in step 105. Afterward, a conductive layer is formed on the activated patterned catalyst material layer, as shown in step 107. In step 107, at least one kind of the metal ions is provided and reduced to metal formed on the activated patterned catalyst material layer, resulting in a conductive layer being formed on the activated patterned catalyst material layer. Also, a boundary exists between the activated patterned catalyst material layer and the conductive layer. In the embodiment, the conductive layer can be formed on the activated patterned catalyst material layer by electroplating or electroless plating (/chemical plating). According to the embodiment, the structure of conductive lines on a substrate comprises an activated patterned catalyst material layer formed from a catalyst material comprising polymer and catalyzer, and a conductive layer (such as a dense metal layer) formed on the activated patterned catalyst material layer. In one embodiment, an uppermost portion of the activated patterned catalyst material layer comprises activated catalysts, and the activated catalysts may include metal (such as reduced from the catalyzer) as a seed layer, so that the conductive layer is formed on the seed layer consequently. Compared to the typical conductive lines formed by the photolithography process (i.e. a dense metal layer directly formed on the substrate, or a dense metal layer formed on the adhesion layer) and by a general printing process (i.e. a conductive layer comprising a mixture of the conductive particles and polymer formed on the substrate), the conductive lines of the embodiment possesses completely different structure.

Embodiments are provided hereinafter with reference to the accompanying drawings for describing the related configurations and procedures, but the present disclosure is not limited thereto. It is noted that not all embodiments of the disclosure are shown. Structures and manufacturing procedures of the embodiments would be different, and could be modified and changed optionally according to the design needs of the application. Modifications and variations can be made without departing from the spirit of the disclosure to meet the requirements of the practical applications. Thus, there may be other embodiments of the present disclosure which are not specifically illustrated. It is also important to point out that the illustrations may not be necessarily be drawn to scale. Thus, the specification and the drawings are to be regard as an illustrative sense rather than a restrictive sense.

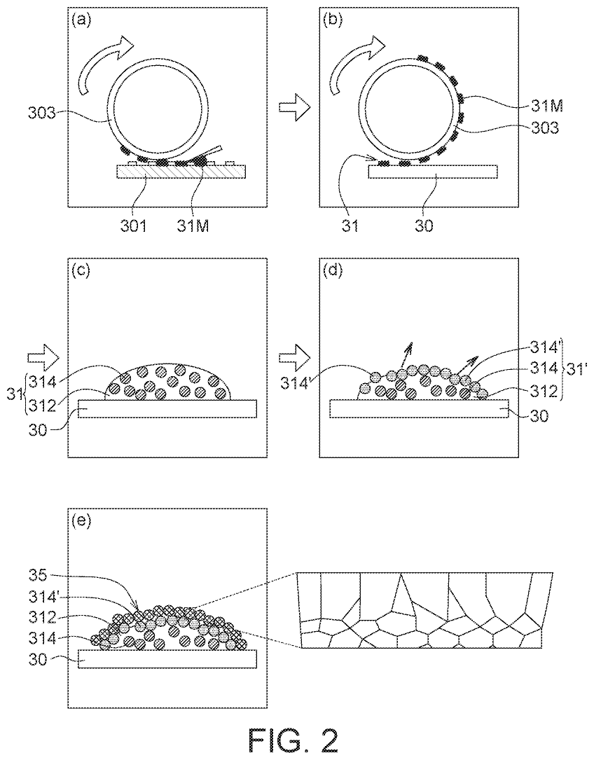

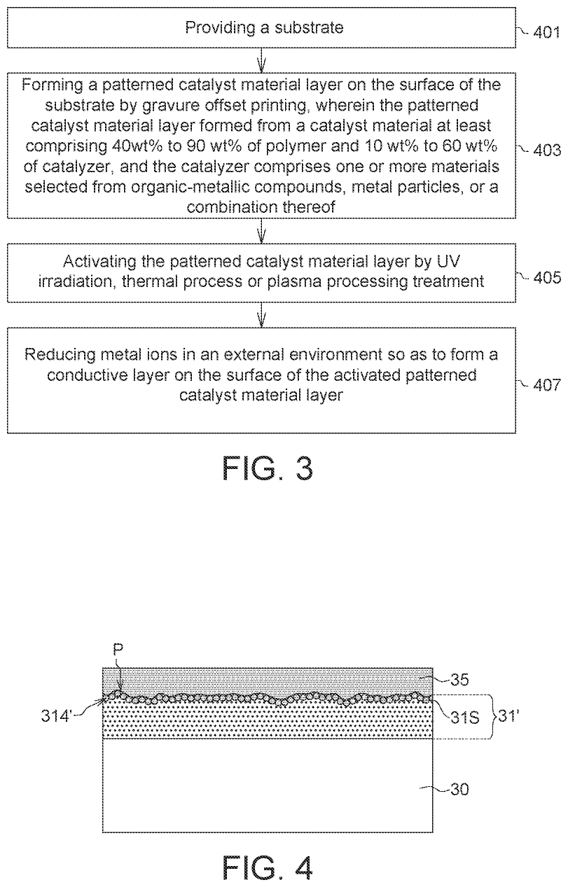

FIG. 2 illustrates a method of manufacturing of a structure of conductive lines on a substrate by a gravure offset printing process according to an embodiment of the disclosure. FIG. 3 is a method of manufacturing of a structure of conductive lines on a substrate according to one of the embodiments. Please refer to FIG. 2 and FIG. 3.

In one embodiment, after a substrate is provided as shown in step 401, the catalyst material as prepared is printed on the surface of the substrate by gravure offset printing to form a patterned catalyst material layer, and the catalyst material at least comprises 40 wt % to 90 wt % of polymer and 10 wt % to 60 wt % of catalyzer, as shown in step 403. Please refer to FIG. 2. In the gravure offset printing process, the catalyst material 31M as prepared is filled into the grooves of a gravure plate 301, and transferred to a transferring medium 303 such as a blanket roll for picking up the catalyst material 31M (step (a)), and then printed onto the surface of the substrate 30 to form a patterned catalyst material layer 31 (step (b)).

In one embodiment, the catalyst material 31M comprises 40 wt % to 90 wt % of polymer and 10 wt % to 60 wt % of catalyzer. The catalyst material 31M is printed onto the surface of the substrate 30 through the transferring medium 303.

In one embodiment, the patterned catalyst material layer 31 is a gelatinous layer and formed from the catalyst material 31M, wherein the catalyst material 31M comprises 40 wt % to 90 wt % of polymer 312 and 10 wt % to 60 wt % of catalyzer 314, as shown in step (c) of FIG. 2. The polymer 312 may comprise one or more materials selected from acrylate resin, epoxy resin, phenol resin, or a combination thereof. In one embodiment, the catalyzer 314 may comprise one or more materials selected from organic-metallic compounds, metal particles (/metallic granules), or a combination thereof. In one embodiment, the catalyzer 314 may comprise silver acetate, copper particles (/granules), silver particles (/granules), or a combination thereof. However, the present disclosure has no particular limitation to the materials described herein. Other polymer materials suitable for the gravure offset printing process and capable of being well-mixed with the selected catalyzer can be applied in the embodiment of the disclosure. Also, other catalyzer materials capable of being activated by appropriate treatment for reducing metal ions to generate a metal layer can be applied in the embodiment of the disclosure. Those materials as described have been provided for exemplification, not for limitation of the disclosure.

Subsequently, the patterned catalyst material layer 31 is activated, such as by UV irradiation, thermal process (heating treatment/heating process), or plasma processing treatment, as shown in step (c) of FIG. 2 and step 405 of FIG. 3. The patterned catalyst material layer 31 is activated to form an activated patterned catalyst material layer 31′, wherein an uppermost portion of the activated patterned catalyst material layer 31′ comprises the activated catalysts 314′, as shown in step (d) of FIG. 2. Also, the arrows shown in step (d) denote gas produced in the activation, such as hydrocarbon, carbon dioxide, carbon monooxide, water and hydrogen chloride.

In addition to the mixture of the polymer 312 and the catalyzer 314 of the patterned catalyst material layer 31 on the substrate 30, other additives can be added into the mixture, depending on the method of activating treatment, the characteristics of the patterned catalyst material layer 31, and/or other factors. For examples, if the patterned catalyst material layer 31 is activated by UV irradiation in one embodiment, a photoinitiator is added into the patterned catalyst material layer 31. Additionally, if the patterned catalyst material layer 31 is activated by a thermal process in one embodiment, a heating treatment such as heating at a high temperature can be adopted for activating the patterned catalyst material layer 31, wherein the heating temperature and time are determined according to the practical materials of the polymer 312 and the catalyzer 314.

Furthermore, in one embodiment, a surface tension of the catalyst material 31M is a range of 20 mN/m to 40 mN/m, and this catalyst material 31M is suitable for being printed on the surface of the substrate 30 in the gravure offset printing process. In the catalyst material 31M, the polymer material having a surface tension near to or in the range of 20 mN/m to 40 mN/m can be selected for being the polymer 312 of the embodiment; however, the disclosure is not limited thereto. In other embodiment, if the polymer 312 as selected has a surface tension off this range, an adequate surface tension additive can be added for adjusting the surface tension of the mixture of the catalyst material 31M to be suitable for use in the gravure offset printing process. Also, a viscosity modifier can be optionally added into the mixture of the catalyst material 31M, for adjusting the viscosity of catalyst material 31M to be suitable for use in the gravure offset printing process.

Subsequently, an external environment with metal ions is provided for the activated patterned catalyst material layer 31′. For example, at least one kind of the metal ions is provided to be in contact with the patterned catalyst material layer 31′, so that a conductive layer 35 is formed on the patterned catalyst material layer 31′. In one embodiment, the metal ions in the external environment can be reduced and formed on the activated patterned catalyst material layer 31′, so that a conductive layer 35 is formed on a surface of the activated patterned catalyst material layer 31′, as shown in step 407 of FIG. 3. In a further embodiment, the activated catalysts 314′ (positioned at the uppermost portion of the activated patterned catalyst material layer 31′) comprises metal reduced from the catalyzer 314, such as silver atoms (Ag) reduced from the catalyzer 314, and functions as a seed layer, wherein the conductive layer 35 is formed on the seed layer, as shown in step (e) of FIG. 2. Take an external environment (i.e. a chemical plating solution) containing copper sulfate (CuSO₄) and formaldehyde (CH₂O) for example. Formaldehyde (CH₂O) is a reducing agent that can reduce copper ions in copper sulfate (CuSO₄) to generate copper (Cu), and produce sulfate ions (SO₄⁻) and formate acid (HCOOH). When the activation step is performed, the activated catalysts 314′ (for example, metal silver atom (Ag)) can catalyze the redox reaction in the electroless plating solution to reduce the copper ions (Cu²⁺) in the copper sulfate, and the reduced copper (Cu) is formed on the seed layer (i.e., the activated catalysts 314′ such as metal Ag) to produce a dense conductive layer 35 (such as a dense copper layer). Accordingly, in one example, the conductive layer 35 comprises a metal material (e.g. Cu) different from the metal (e.g. Ag) reduced from the catalyzer.

Practically, the substrate 30 with the activated patterned catalyst material layer 31′ thereon can be immersed into a plating solution for conducting an electroplating reaction or an electroless plating(/chemical plating) reaction, so as to catalyze reduction of the metal ions in the plating solution and grow a dense conductive layer 35 (i.e. a dense metal layer which is formed continuously and possessing high conductivity as pure metal does) on the surface of the activated patterned catalyst material layer (such as formed on the activated catalysts 314′ of the activated patterned catalyst material layer 31′). In one example, the plating solution comprises copper sulfate, and a dense copper layer is grown on the surface of the activated patterned catalyst material layer. Accordingly, a structure of conductive lines on a substrate may include: an activated patterned catalyst material layer 31′ (may comprising polymer 312, activated catalysts 314′, and possibly further comprising non-activated catalysts 314 from the catalyst material 31M) on the substrate 30, and a conductive layer 35 (e.g. a dense metal layer) formed on the activated catalysts 314′ of the activated patterned catalyst material layer 31′, wherein an uppermost portion of the activated patterned catalyst material layer 31′ comprises activated catalysts 314′ (comprising metal reduced from the catalyzer) functioning as a seed layer. That is, the conductive layer 35 is formed on the seed layer. Therefore, in the structure comprising conductive lines of one embodiment, a thin layer of metal atoms (metal particles) as reduced from the catalyzer 314 can be observed under the conductive layer 35; thus, a three-layered structure of one embodiment at least having a polymer layer, a layer of activated catalysts (e.g. a seed layer) and a conductive layer (e.g. a dense metal layer) would be observed.

FIG. 4 illustrates a structure of conductive lines manufactured according to a method of one embodiment of the disclosure. According to one of the manufacturing methods of the embodiment, a layer of the activated catalysts 314′ (e.g. metals such as silver atoms) reduced from the catalyzer 314 functions as a seed layer, and the activated catalysts 314′ catalyze the reduction of metal ions in the plating solution (e.g. Cu2+ reduced to Cu). The metals as reduced (such as Cu) from the metal ions in the plating solution are formed on the seed layer. Accordingly, a structure of conductive lines on a substrate 30 includes an activated patterned catalyst material layer 31′ having activated catalysts 314′ (as a seed layer), and a conductive layer 35 formed on the activated catalysts 314′ of the activated patterned catalyst material layer 31′. From a top view of the substrate 30, a pattern of the conductive layer 35 would be corresponds (e.g. being substantially identical) to the activated patterned catalyst material layer 31′. From a cross-sectional view of the embodied structure of conductive lines, it may show a three-layered structure (i.e. a layer comprising polymer/a seed layer/a conductive layer). As shown in FIG. 4, the uppermost portion of the activated patterned catalyst material layer 31′ is a seed layer 31S, which comprises activated catalysts 314′; also, the conductive layer 35 is produced on the seed layer 31S. In one embodiment, it is observed that a boundary P exists between the seed layer 31S (comprising activated catalysts 314′) of the activated patterned catalyst material layer 31′ and the conductive layer 35, and the boundary is substantially a flat surface. In one embodiment, the boundary P is substantially parallel to a surface of the substrate 30.

Physical properties of the structure of conductive lines of the embodiment have also been measured and observed. In one example, a patterned catalyst material layer of the embodiment is activated by UV irradiation (365 nm)(e.g. the activated catalysts comprises metal reduced from the catalyzer). Those samples are exposed to different UV energy. After activation, it is observed that the activated catalysts of the activated patterned catalyst material layer comprising metal atoms (such as silver atoms reduced from the catalyzer) have been shown at the surface of the activated patterned catalyst material layer. Also, the average particle size of the activated catalysts (i.e. metal atoms) has also been measured. For example, when the patterned catalyst material layer is exposed to 0.93 J/cm³ of UV irradiation (365 nm), the average particle size of the activated catalysts shown at the surface of the activated patterned catalyst material layer is about 0.5 μm. For example, when the patterned catalyst material layer is exposed to 1.84 J/cm³ of UV irradiation (365 nm), the average particle size of the activated catalysts shown at the surface of the activated patterned catalyst material layer is about 1.7 μm. In one embodiment, the average particle size of the activated catalysts shown at the surface of the activated patterned catalyst material layer is in a range of 0.5 μm to 2.0 μm. However, those numerical values are provided for illustration, not for limitation.

According to the manufacturing method of the embodiment, the conductive lines with high conductivity can be obtained, and the line widths of the conductive lines can be larger than 0 μm and equal to or smaller than 30 μm. In one embodiment, the line widths of the conductive lines can be equal to or larger than 20 μm, and equal to or smaller than 30 μm. In one embodiment, the line widths of the conductive lines can be larger than 0 μm, and equal to or smaller than 20 μm. In other embodiment, the line widths of the conductive lines can be decreased to about 10 μm, even in a range of larger than 0 μm and equal to or smaller than 10 μm. According to an embodiment of the disclosure, PCB (printed circuit board) traces applied by the conductive lines with high conductivity of the embodiment, which is manufactured by catalyst material formed by gravure offset printing and selective metal plating (e.g. selective copper plating), have the line widths of about 10 μm, and the resistance of traces can be reduced to about 0.0150, and the electrical properties thereof is very similar to the conductive lines made of pure metal.

The cross-sectional profiles of the structures of conductive lines manufactured by conventional methods (e.g. photolithography and deriving process, printing and deriving process) and the method of the embodiment are completely different. According to the conductive lines manufactured by a typical photolithography, the cross-sectional profile of the structure of conductive lines includes one dense metallic adhesion layer comprising metal (such as chromium, titanium . . . etc.), and a dense metal layer (such as silver, gold, copper . . . etc.) deposited on the surface of the dense metallic adhesion layer by sputtering or deposition. Thus, both layers of the conventional structure of conductive lines manufactured by photolithography are metal layers. According to the conductive lines manufactured by a typical printing process, the cross-sectional profile of the structure of conductive lines has one conductive composite layer comprising conductive fillers (such as granules of silver, copper, gold, tin . . . etc.) and dispersed in a polymeric material. According to the conductive lines of the embodiment, the cross-sectional profile of the structure of conductive lines has an activated patterned catalyst material layer (comprising polymer and catalyzer) formed on a surface of a substrate, and a dense conductive layer (such as dense metal layer) formed on the activated patterned catalyst material layer using electroplating or electroless plating (/chemical plating), wherein a pattern of the dense conductive layer corresponds (e.g. being substantially identical) to the activated patterned catalyst material layer. As described above, in one example, an uppermost portion of the activated patterned catalyst material layer 31′ comprises a seed layer 31S containing activated catalysts 314′ (such as metal reduced from the catalyzer 314), and the conductive layer 35 is formed on the seed layer 31S the activated patterned catalyst material layer 31′.

Therefore, the cross-sectional profile of the structure of conductive lines manufactured by photolithography comprises stacked metal layers with high conductivity, but the photolithography process requires an expansive and large-scale vacuum system. Although the method for forming the conductive lines by printing process is quick, the electrical properties of the conductive lines need to be improved and the resistance to bending is bad (no stretchability as stretchable metal does). The method of manufacturing a structure of conductive lines according to the embodiment possesses several advantages such as low-production cost, rapid manufacturing procedures, high yield of production (since no notch defect typically occurs in the photolithography process would be shown in the structure of the embodiment, the problem of disconnection lines is successfully avoided), and high conductivity since the electrical properties of the embodied conductive lines are similar to the conductive lines manufactured by the photolithography process.

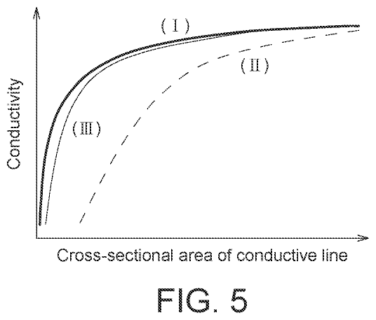

FIG. 5 shows the relationship of conductivity versus cross-sectional area of the conductive lines manufactured by the photolithography process, the printing process and the embodied manufacturing method. Curve (I) represents the relationship of conductivity versus cross-sectional area of the pure metal lines manufactured by the photolithography process. Curve (II) represents the relationship of conductivity versus cross-sectional area of the conductive lines (i.e. mixture of polymer and conductive fillers) manufactured by the printing process. Curve (III) represents the relationship of conductivity versus cross-sectional area of the conductive lines manufactured by the embodied manufacturing method. As shown in FIG. 5, a dense metal layer is formed on the substrate by photolithography (i.e. Curve (I)), and the conductivity thereof is increased with the increase of the cross-sectional area of the metal layer, and the dense metal layer has the highest conductivity. In the printing process, the conductive lines are made from a mixture of polymer and conductive fillers (i.e. Curve (II)) and the conductive fillers are melted by sintering at a high temperature, but they are not a dense metal, and the conductivity thereof is noticeably dropped with the decrease of the cross-sectional area of the conductive line. According to the disclosure, a patterned catalyst material layer (e.g. not limitedly made of low-conductive or non-conductive material, and the thickness could be smaller than 3 μm) is printed on the substrate, followed by activating and contacting one kind of metal ions as provided to the activated patterned catalyst material layer, such as by electroless plating or electroplating, so as to form a dense conductive layer on the activated patterned catalyst material layer. Accordingly, under the same cross-sectional area of the conductive lines, the cross-sectional profile of the embodied structure of conductive lines comprises a dense conductive layer. Although there is a slight differences between the electrical properties of the structures manufactured by photolithography and embodied method (i.e. Curve (I) and Curve (III)), the electrical properties of the structures manufactured by those methods are very similar. Also, the conductivity of the conductive lines manufactured by typical printing process (i.e. Curve (II)) is not as good as that manufactured by the embodied method.

Several applicable methods according to the embodiments for manufacturing the embodied structure of the conductive lines are disclosed below. However, steps and related numerical values provided in each of the embodiments are exemplified for illustrating one of applicable procedures, not for limiting the scope of protection of the disclosure.

### First Embodiment

In the first embodiment, a catalyst material is transferred to a transferring medium, and then printed onto the surface of 7 μm polyimide (PI, i.e. the substrate) by a gravure offset printing process to form a trace pattern (i.e. a patterned catalyst material layer) having line width of 20 μm to 100 μm and film thickness smaller than 1 μm. Then, the substrate (PI) is baked in the oven at 120° C. for 30 minutes to activate the catalyzer of the catalyst material (for example, silver acetate is activated to produce silver atoms, and those silver atoms move to the upper portion of the activated patterned catalyst material layer and form a seed layer). The catalyst material contains 1 g polyacrylate-epoxy resin (type: 395, available from Chembridge), 0.1 g phenol (type: 3760, available from Chembridge) and 0.2 g silver acetate (available from SIGMA), wherein a surface tension of the catalyst material is 23.8 mN/m. Afterward, the substrate with the activated patterned catalyst material layer thereon is immersed into a plating solution containing copper sulfate to proceed the reduction reaction. In one embodiment, the plating solution contains 14.9 g/L copper sulfate, 35.1 g/L ethylenediaminetetraacetic acid (EDTA) and 10 mL/L formaldehyde. After heating at 75° C. for 30 minutes, the metal ions in the plating solution are reduced and formed on the activated patterned catalyst material layer, and a dense conductive layer is grown on the surface of the activated patterned catalyst material layer, such as grown on the seed layer 31S as shown in FIG. 4. According to the first embodiment, a structure of conductive lines with high conductivity can be obtained using the gravure offset printing process, and the conductivity of the embodied structure is almost as good as the pure copper trace does.

### Second Embodiment

In the second embodiment, a metal net structure of the conductive lines is formed by a gravure offset printing process, and the sheet resistance of the metal net structure is detected. The catalyst material contains 1 g polyacrylate-epoxy resin (type: 395, available from Chembridge), 0.1 g phenol (type: 3760, available from Chembridge), 0.3 g silver acetate (available from SIGMA) and 0.1 g silver nano-particles with 20 nm diameter in average. Addition of the silver nano-particles may contribute to the increasing activity for the electroless plating, thereby increasing the plating rate of the electroless plating. After the surface tension test, it is observed that the surface tension of the catalyst material with silver nano-particles has about 1.7 mN/m more than that without addition of silver nano-particles, and reaches about 25.5 mN/m. In the second embodiment, a catalyst material is transferred to a transferring medium and then printed onto the surface of polyethylene terephthalate (PET, i.e. the substrate) by a gravure offset printing process to form a trace pattern (i.e. a patterned catalyst material layer). Then, the substrate (PET) with the catalyst material formed thereon is baked in the oven at 120° C. for 30 minutes to activate the catalyst material (for example, silver acetate is activated to produce silver atoms, and those silver atoms move to the upper portion of the activated patterned catalyst material layer and form a seed layer). Afterward, the substrate with the activated patterned catalyst material layer thereon is immersed into a plating solution (contains 14.9 g/L copper sulfate, 35.1 g/L ethylenediaminetetraacetic acid (EDTA) and 10 mL/L formaldehyde)(heated at 75° C. for 30 minutes) to grow a dense copper layer on the surface of the activated patterned catalyst material layer (such as grown on the seed layer 31S for about 15 minutes of electroless plating), thereby improving the conductive properties of the conductive lines. In the second embodiment, a metal net structure of the conductive lines with a line width of about 8.9 μm and a periodicity of 1000 is tested, and the experimental results indicated that the sheet resistant thereof is 1400 mΩ/□ (transmittance 90.4%). Therefore, the metal net structure of the conductive lines manufactured by the embodied method has similar conductive properties to the pure copper. Accordingly, in the second embodiment, a metal net structure of the conductive lines (i.e. 8.9 μm of line width and 1000 of periodicity) with high conductivity can be obtained using the gravure offset printing process.

### Third Embodiment

In the third embodiment, a metal net structure of the conductive lines is formed by a gravure offset printing process, and the sheet resistance of the metal net structure is detected. The manufacturing procedures of the third embodiment are similar to that of the second embodiment, which are not redundantly repeated.

In the third embodiment, a metal net structure of the conductive lines with a line width of about 9.2 μm and a periodicity of 600 is tested, and the experimental results indicated that the sheet resistant thereof is 26.7 mΩ/□ (transmittance 88.6%). Therefore, the metal net structure of the conductive lines manufactured by the embodied method has similar conductive properties to the pure copper. Accordingly, in the third embodiment, a metal net structure of the conductive lines (i.e. 9.2 μm of line width and 600 of periodicity) with high conductivity can be obtained using the gravure offset printing process.

### Fourth Embodiment

In the fourth embodiment, a flexible printed circuit board (FPCB) applied by the embodied structure is provided. The catalyst material is transferred to a transferring medium and then printed onto the surface of polyimide (Pl, i.e. the substrate) by a gravure offset printing process to form a trace pattern (i.e. a patterned catalyst material layer). The catalyst material contains 1 g polyacrylate-epoxy resin (type: 395, available from Chembridge), 0.1 g phenol (type: 3760, available from Chembridge), 0.2 g silver acetate (available from SIGMA) and 0.21 g of surface tension modifier, wherein a surface tension of the catalyst material is 37.6 mN/m. After activation at 180° C. for 30 minutes (e.g. silver acetate is activated to produce silver atoms as a seed layer), the substrate with the activated patterned catalyst material layer thereon is immersed into a plating solution containing copper sulfate to proceed the reduction reaction for about 30 minutes (i.e. reducing copper ions, and forming a copper layer on the activated patterned catalyst material layer)(the plating solution contains 14.9 g/L copper sulfate, 35.1 g/L ethylenediaminetetraacetic acid (EDTA) and 10 mL/L formaldehyde) to finish the FPCB with conductive lines. Accordingly, in the fourth embodiment, a FPCB with conductive lines with high conductivity can be obtained using the gravure offset printing process, and the line width of the conductive lines is about 10 μm.

### Fifth Embodiment

In the fifth embodiment, the patterned catalyst material layer is activated by UV irradiation. According to the fifth embodiment, the catalyst material is transferred and printed onto the surface of the substrate to form a patterned catalyst material layer, and the patterned catalyst material layer is irradiated by a UV light (365 nm wavelength of the UV light) to activate the patterned catalyst material layer (so as to form). Metal ions in the plating solution are reduced and formed on the activated patterned catalyst material layer (e.g. formed on a seed layer including the activated catalysts), so as to form a dense metal layer on the surface of the activated patterned catalyst material layer. The catalyst material contains 1 g polyacrylate-epoxy resin (type: 395, available from Chembridge), 0.1 g phenol (type: 3760, available from Chembridge), 0.01 g TPO (photoinitiator) and 0.2 g silver acetate (available from SIGMA). In the fifth embodiment, the catalyst material is transferred and printed onto the surface of the PI substrate by a gravure offset printing process to form a trace pattern (i.e. a patterned catalyst material layer), followed by UV irradiation for about 1 minute to activate and cure the patterned catalyst material layer. After activation, the substrate with the activated patterned catalyst material layer (comprising activated catalysts) thereon is immersed into a plating solution (containing 14.9 g/L copper sulfate, 35.1 g/L ethylenediaminetetraacetic acid (EDTA) and 10 mL/L formaldehyde) to grow a dense copper layer on the surface of the activated patterned catalyst material layer (for about 15 minutes of electroless plating to grow on the seed layer 31S), thereby forming a pattern of conductive lines.

### Sixth Embodiment

In the sixth embodiment, the patterned catalyst material layer is activated by a plasma processing treatment. The patterned catalyst material layer containing materials as described in the first embodiment baked in the oven at 120° C. for 5 minutes to vaporize the solvent of the catalyst material, followed by the plasma processing treatment to activate the patterned catalyst material layer. Afterward, the substrate with the activated patterned catalyst material layer thereon is immersed into a plating solution as described in the first embodiment (i.e. contains 14.9 g/L copper sulfate, 35.1 g/L ethylenediaminetetraacetic acid (EDTA) and 10 mL/L formaldehyde) to grow a dense copper layer on the surface of the activated patterned catalyst material layer (15 minutes of electroless plating), thereby forming a pattern of conductive lines.

### Seventh Embodiment

In the seventh embodiment, an epoxy-based resin is adopted in the catalyst material. According to the seventh embodiment, 1 g epoxy resin (type: TC19CW10, available from TeamChem Materials Company) and 0.2 g silver acetate (available from SIGMA) are well-mixed and stirred to form a mixture of the catalyst material, and the catalyst material is transferred and printed onto the surface of the PI substrate by a gravure offset printing process to form a trace pattern (i.e. a patterned catalyst material layer), followed by activation step (as described in the first embodiment) to activate the catalyzer of the patterned catalyst material layer. Afterward, the substrate with the activated patterned catalyst material layer thereon is immersed into a plating solution as described in the first embodiment for 30 minutes, and a dense copper layer is grown on the surface of the activated patterned catalyst material layer.

### Eighth Embodiment

In the eighth embodiment, a phenol-based resin is adopted in the catalyst material. According to the eighth embodiment, 1 g phenol resin (type: 3760, available from Chembridge) and 0.2 g silver acetate (available from SIGMA) are well-mixed and stirred to form a mixture of the catalyst material, and the catalyst material is transferred and printed onto the surface of the PI substrate by a gravure offset printing process to form a trace pattern (i.e. a patterned catalyst material layer), followed by activation step (as described in the first embodiment) to activate the catalyzer of the patterned catalyst material layer. Afterward, the substrate with the activated patterned catalyst material layer thereon is immersed into a plating solution as described in the first embodiment for 30 minutes, and a dense copper layer is grown on the surface of the activated patterned catalyst material layer.

### Ninth Embodiment

In the ninth embodiment, a catalyst material comprising copper particles is adopted. According to the ninth embodiment, 1 g polyacrylate-epoxy resin (type: 395, available from Chembridge), 0.1 g phenol (type: 3760, available from Chembridge) and 3 g copper particles are well-mixed and stirred to form a mixture of the catalyst material, and the catalyst material is transferred and printed onto the surface of the PI substrate by a gravure offset printing process to form a trace pattern (i.e. a patterned catalyst material layer), followed by activation step (as described in the first embodiment) to activate the catalyzer of the patterned catalyst material layer. Afterward, the substrate with the activated patterned catalyst material layer thereon is immersed into a plating solution as described in the first embodiment for 30 minutes, and a dense copper layer is grown on the surface of the activated patterned catalyst material layer.

### Tenth Embodiment

In the tenth embodiment, a catalyst material comprising silver particles is adopted. According to the tenth embodiment, 1 g polyacrylate-epoxy resin (type: 395, available from Chembridge), 0.1 g phenol (type: 3760, available from Chembridge) and 5 g silver particles (20 nm of particle diameters, as the catalyzer) are well-mixed and stirred to form a mixture of the catalyst material, and the catalyst material is transferred and printed onto the surface of the PI substrate by a gravure offset printing process to form a trace pattern (i.e. a patterned catalyst material layer), followed by activation step (as described in the first embodiment) to activate the catalyzer of the patterned catalyst material layer. Afterward, the substrate with the activated patterned catalyst material layer thereon is immersed into a plating solution as described in the first embodiment for 30 minutes, and a dense copper layer is grown on the surface of the activated patterned catalyst material layer.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A method of manufacturing a structure having conductive lines, comprising:
providing a substrate;
forming a patterned catalyst material layer on the substrate, and the patterned catalyst material layer formed from a catalyst material at least comprising 40 wt % to 90 wt % of polymer and 10 wt % to 60 wt % of catalyzer, wherein said catalyzer comprises organic-metallic compounds;
activating the patterned catalyst material layer to form an activated patterned catalyst material layer on the substrate, wherein an uppermost portion of the activated patterned catalyst material layer comprises activated catalysts after activating, and the activated catalysts comprises metal reduced from the catalyzer; and
contacting metal ions as provided to the activated patterned catalyst material layer, so as to form a conductive layer on the activated catalysts of the activated patterned catalyst material layer.

2. The method according to claim 1, wherein the metal reduced from the catalyzer functions as a seed layer, and the conductive layer is formed on the seed layer.

3. The method according to claim 1, wherein the metal reduced from the catalyzer has an average particle size in a range of 0.1 μm to 2.0 μm.

4. The method according to claim 1, wherein the conductive layer comprises a metal material different from the metal reduced from the catalyzer.

5. The method according to claim 1, wherein the patterned catalyst material layer is formed on the substrate.

6. The method according to claim 1 wherein the patterned catalyst material layer is activated by UV irradiation, thermal process, or plasma processing treatment.

7. The method according to claim 1, wherein said metal ions in an external environment are reduced and formed on the activated catalysts of the activated patterned catalyst material layer, thereby forming the conductive layer on a surface of the activated catalysts of the activated patterned catalyst material layer.

8. The method according to claim 1, wherein the activated patterned catalyst material layer on the substrate is immersed into a plating solution, and the conductive layer is grown on a surface of the activated catalysts of the activated patterned catalyst material layer by reducing said metal ions in the plating solution.

9. The method according to claim 1, wherein said polymer the catalyst material comprises one or more materials selected from acrylate resin, epoxy resin, phenol resin, or a combination thereof.

10. The method according to claim 1, wherein said catalyzer of the catalyst material comprises silver acetate.
